(19) United States
(12) Patent Application Publication
(10) Pub. No.: US 2013/0076340 A1
(43) Pub. Date: Mar. 28, 2013

(54) REED SWITCH CHAIN TO DETECT METER TAMPERING

(71) Applicants: Didier Gilbert Rouaud, Kennesaw, GA (US); David John Sevey, Rochester, NH (US)

(72) Inventors: Didier Gilbert Rouaud, Kennesaw, GA (US); David John Sevey, Rochester, NH (US)

(73) Assignee: GENERAL ELECTRIC COMPANY, Schenectady, NY (US)

(21) Appl. No.: 13/242,805

(22) Filed: Sep. 23, 2011

(51) Int. Cl. G01R 1/00

(52) U.S. Cl. 324/110

(57) ABSTRACT

Aspects of the invention provide for detecting tampering with an electronic utility meter. In one embodiment, aspects of the invention include an electronic utility meter, comprising a metering circuit enclosed within a cover; a switch chain including at least one reed switch operatively coupled to the metering circuit, and positioned around an inner circumference of the cover; and a sensor enclosed within the cover, coupled to the switch chain, the sensor sensing the at least one three reed switch closing in response to a user interaction with the electronic utility meter.

### BACKGROUND OF THE INVENTION

The subject matter disclosed herein relates generally to electronic utility meters. More specifically, the present disclosure relates to a reed switch detection system to detect meter tampering.

Electronic utility meters are used to measure usage of a utility, for example, electricity, gas, or water. Current transformers within the base of the electronic utility meters are used to measure the current flow. The measured current flow indicates the amount of usage, which is sent to the utility service/company.

One of the major concerns for utility companies is electronic utility meter tampering. Utility companies want to prevent customers from being able to tamper with the electronic utility meter and ensure that the electronic utility meter accurately measures the customer's usage.

### BRIEF DESCRIPTION OF THE INVENTION

Aspects of the invention provide for detecting tampering with an electronic utility meter. In one embodiment, aspects of the invention include an electronic utility meter, comprising a metering circuit enclosed within a cover; a switch chain including at least three reed switches operatively coupled to the metering circuit, and positioned around an inner circumference of the cover; and a sensor enclosed within the cover, coupled to the switch chain, the sensor sensing at least one of the at least three reed switches closing in response to a user interaction with the electronic utility meter.

A first aspect of the invention provides an electronic utility meter, comprising: a metering circuit enclosed within a cover; a switch chain including at least one reed switch operatively coupled to the metering circuit, and positioned around an inner circumference of the cover; and a sensor enclosed within the cover, coupled to the switch chain, the sensor sensing the at least one reed switch closing in response to a user interaction with the electronic utility meter.

A second aspect of the invention provides a device, comprising: a metering circuit for metering a utility service within a utility system, the metering circuit enclosed within a cover; a switch chain including at least one reed switch operatively coupled to the metering circuit, and positioned around an inner circumference of the cover; a sensor enclosed within the cover, coupled to the switch chain, the sensor sensing the at least one reed switch closing in response to a user interaction with the electronic utility meter; and a communication module for generating an alarm to send to a utility company in response to the at least one reed switch closing.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a partial schematic diagram of an electronic utility meter according to aspects of the invention;

FIG. 2 shows a partial perspective view of an electronic utility meter according to aspects of the invention;

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

The subject matter disclosed herein relates generally to electronic utility meters. More specifically, the present disclosure relates to a reed switch detection system to detect meter tampering.

Electronic utility meters are used to measure usage of a utility, for example, electricity, gas, or water. Current transformers within the base of the electronic utility meters are used to measure the current flow. The measured current flow indicates the amount of usage, which is sent to the utility service/company.

One of the major concerns for utility companies is electronic utility meter tampering. Utility companies want to prevent customers from being able to tamper with the electronic utility meter and ensure that the electronic utility meter accurately measures the customer's usage.

One of the methods of electronic utility meter tampering is to use a high intensity magnet and apply it to the cover of the electronic utility meter. The high intensity of the magnet may saturate one or more of the current transformers within the meter that are used to measure the current flow. In most cases, the current transformer, when saturated, will only read approximately 50% or less of the correct usage.

Aspects of the invention provide for detecting tampering with an electronic utility meter. In one embodiment, aspects of the invention include an electronic utility meter, comprising a metering circuit enclosed within a cover; a switch chain including at least three reed switches operatively coupled to the metering circuit, and positioned around an inner circumference of the cover; and a sensor enclosed within the cover, coupled to the switch chain, the sensor sensing at least one of the at least three reed switches closing in response to a user interaction with the electronic utility meter.

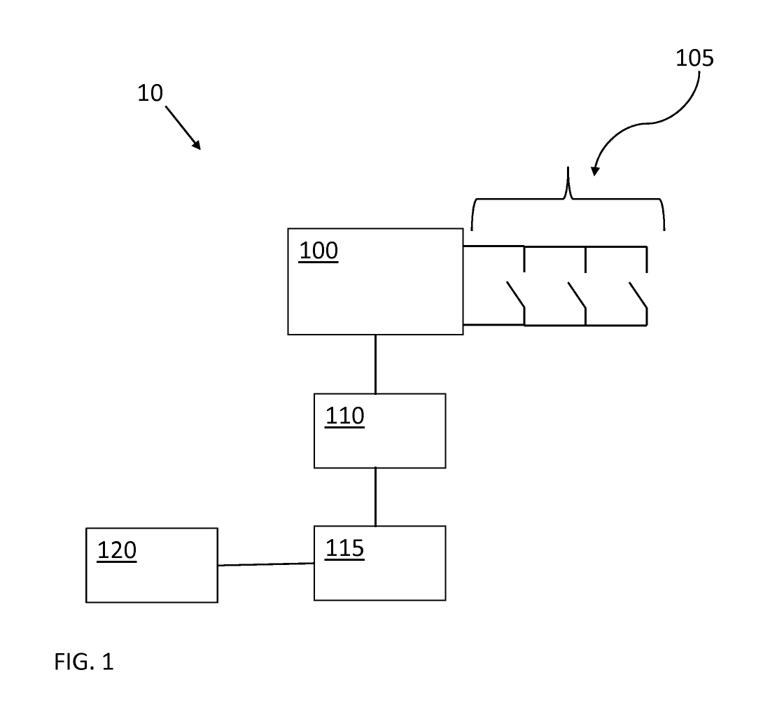

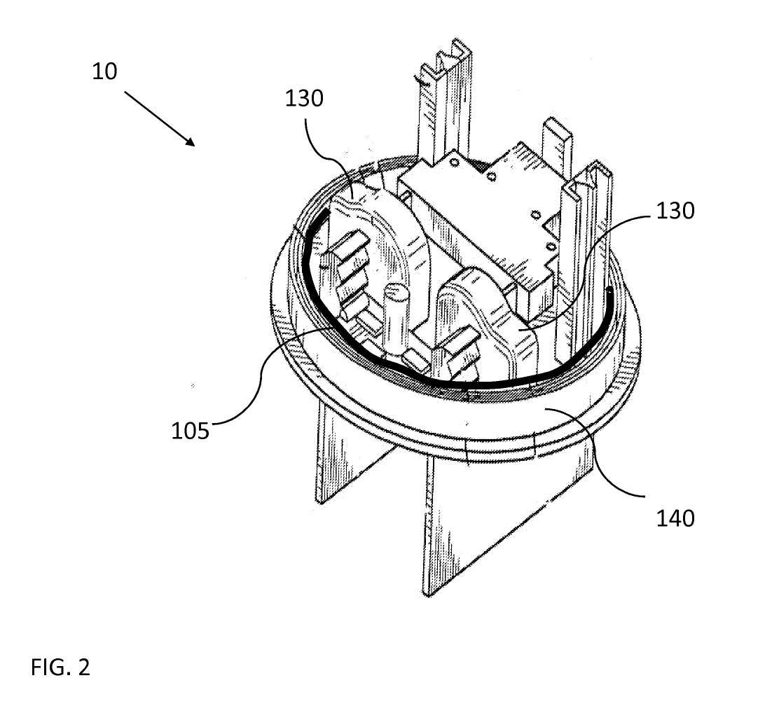

Turning now to FIG. 1, a partial schematic diagram of an electronic utility meter 10 according to aspects of the invention is shown. The electronic utility meter 10 includes a metering circuit 100 enclosed within a cover 140 (FIG. 2). The metering circuit 100 includes conventional meter circuitry, as known in the art. The specific details of the metering circuit 100 are omitted herein for clarity purposes.

As shown in FIG. 1, the electronic utility meter 10 includes a switch chain 105. The switch chain 105 includes at least three reed switches connected in parallel. The switch chain 105 is operatively coupled to the metering circuit 100. As will be described with respect to FIG. 2, the switch chain 105 is positioned around an inner circumference of the cover 140 (FIG. 2).

A reed switch, as known in the art, is an electrical switch that is operated by an applied magnetic field. In operation, the contacts of the switch remain open until a magnetic field is present, and in response to the magnetic field, the contacts of the switch will close. Alternatively, the contacts of the switch may remain closed, and open, in response to the magnetic field.

The electronic utility meter 10 also includes a sensor 110, which may also be enclosed within the cover 140 (FIG. 2). The sensor 110 is coupled to the metering circuit 100, and also the switch chain 105 (not shown). The sensor 110 will sense when at least one of the reed switches in the switch 105 closes (or opens) in response to a user interaction with the electronic utility meter 10. That is, the switch 105 will close (or open) in response to a user applying a high magnetic field to the electric utility meter 10. In this case, the tampering with the electronic utility meter 10 may be detected by the switch chain 105 and the sensor 110.

The electronic utility meter 10 may also include a communication module 115 for generating an alarm to send to a utility company (not shown) in response to at least one of the reed switches of the switch chain 105 closing (or opening). In one embodiment, the communication module may send the alarm immediately after one of the reed switches of the switch chain 105 closes (or opens). Alternatively, the communication module may send the alarm after a predetermined amount of time after one of the reed switches of the switch chain 105 closes (or opens). The electronic utility meter 10 may also include a computer readable storage device 120 for logging the alarm.

Turning now to FIG. 2, a partial perspective view of the electronic utility meter 10 according to aspects of the invention is shown. The remaining portions, such as the cover, have been omitted for clarity purposes. As mentioned above, the switch chain 105 may be positioned around an inner circumference of the cover 140. The reed switches of the switch chain 105 may be within an insulation tubing, as seen in FIG. 2, such that the reed switches are in parallel.

Although only two current transformers 130 are shown in the electronic utility meter 10 of FIG. 2, it is understood that the electronic utility meter 10 according to aspects of the invention may include any number of current transformers. For example, the metering circuit 100 of the electronic utility meter 10 may include three current transformers 130 for a three-phase system. However, the metering circuit 100 may be applied to other systems, as known in the art, such as a single phase system or a dual phase system.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An electronic utility meter, comprising:
a metering circuit enclosed within a cover;
a switch chain including at least one reed switch operatively coupled to the metering circuit, and positioned around an inner circumference of the cover; and
a sensor enclosed within the cover, coupled to the switch chain, the sensor sensing the at least one reed switch closing in response to a user interaction with the electronic utility meter.

2. The electronic utility meter of claim 1, wherein the metering circuit includes at least one current transformer.

3. The electronic utility meter of claim 1, further comprising a communication module for generating an alarm to send to a utility company in response to the at least one three reed switch closing.

4. The electronic utility meter of claim 3, wherein the communication module sends the alarm to the utility company after a predetermined amount of time.

5. The electronic utility meter of claim 4, further comprising a computer readable storage device for logging the alarm.

6. The electronic utility meter of claim 1, wherein the switch chain is enclosed within insulation.

7. A device, comprising:
a metering circuit for metering a utility service within a utility system, the metering circuit enclosed within a cover;
a switch chain including at least one reed switch operatively coupled to the metering circuit, and positioned around an inner circumference of the cover;
a sensor enclosed within the cover, coupled to the switch chain, the sensor sensing the at least one reed switch closing in response to a user interaction with the electronic utility meter; and
a communication module for generating an alarm to send to a utility company in response to the at least one reed switch closing.

8. The device of claim 7, wherein the metering circuit includes at least one current transformers.

9. The device of claim 7, wherein the communication module sends the alarm to the utility company after a predetermined amount of time.

10. The device of claim 8, further comprising a computer readable storage device for logging the alarm.

11. The device of claim 7, wherein the switch chain is enclosed within insulation.
